(19) United States
(12) Patent Application Publication
(10) Pub. No.: US 2009/0266412 A1
(43) Pub. Date: Oct. 29, 2009

(54) Solar Cell, Prefabricated Base Part for a Solar Cell and Method for Manufacturing Such a Base Part and a Solar Cell

(76) Inventor: Antulio Tarazona Labrador, West Sussex (GB)

Correspondence Address: Walter A Hackler;Patent Law Office, 2372 S E Bristol Street, Suite B, Newport Beach, CA, 92660-0755, US

(21) Appl. No.: 12/225,605

(22) PCT Filed: Mar. 31, 2006
(86) PCT No.: PCT/EP2006/002947

§ 371 Date: Sep. 25, 2008

(51) Int. Cl. H01L 31/00; H05K 1/09; H05K 3/10; H01L 21/28

(52) U.S. Cl. 136/255; 174/251; 29/846; 438/57; 257/E21.158

(57) ABSTRACT

The invention refers to a solar cell comprising a p-doped semiconductor layer and a n-doped semiconductor layer arranged on a substrate between a front electrode and a back electrode, the front electrode being arranged between the substrate and the semiconductor layers, and in that the front electrode is formed by at least one metal wire. The invention also refers to a prefabricated base part for manufacturing such a solar cell, the base part includes a substrate in which at least one metal wire is embedded in such a way that only part of its circumference is surrounded by the substrate. The invention also refers to methods for manufacturing such base parts and solar cells.

The invention refers to a solar cell comprising at least one p-doped semiconductor layer and at least one n-doped semiconductor layer arranged on a substrate between a front electrode and a back electrode, the front electrode being arranged between the substrate and the semiconductor layers. The invention also refers to a prefabricated base part for manufacturing such a solar cell and methods for manufacturing such base parts and solar cells.

According to the state of the art the front electrode of solar cells of the above-mentioned kind is formed by a transparent electrically conductive oxide layer, for example indium tin oxide. Substrates covered with a layer of a transparent conductive oxide can be bought as prefabricated base parts for manufacturing solar cells. During the manufacturing process of thin film solar cells semiconductor layers are deposited on the transparent conductive oxide layer.

However, properties of the transparent conductive oxide layer prevent heat treatment of the deposited semiconductor layers which would be desirable to increase their crystallinity, as solar cells of crystalline semiconductor material are typically more efficient and stable than solar cells of amorphous material.

An object of the present invention is therefore to show a way to improve the crystallinity of semiconductor layers of a solar cell.

### SUMMARY OF THE INVENTION

A solar cell according to the invention comprises at least one p-doped semiconductor layer and at least one n-doped semiconductor layer arranged on a substrate between a front electrode and a back electrode, the front electrode being arranged between the substrate and the semiconductor layers, characterized in that the front electrode is formed by at least one metal wire.

The invention also refers to a prefabricated base part for manufacturing such a solar cell, said base part comprising a substrate in which at least one metal wire is embedded in such a way that only part of its cross-section is surrounded by the substrate. Hence, part of the cross-section of the at least one wire is exposed.

The invention also refers to a method for manufacturing such a base part, said method comprising the following step: embedding at least one metal wire in the substrate in such a way that only part of its cross-section is surrounded by the substrate.

The invention also refers to a method for manufacturing such a solar cell using such a base part, said method comprising the following steps: depositing an n-doped and a p-doped semiconductor layer onto a base part, which comprises a substrate and at least one embedded wire, in such a way that they are electrically connected to the at least one wire, and placing the back electrode on top of the semiconductor layers.

According to the invention the front electrode of the solar cell is formed by at least one metal wire. Thus a transparent conductive oxide is no longer needed and the semiconductor layers can be deposited onto a hot substrate or heat-treated after they are deposited on the substrate. Heat treatment can therefore be used to improve the crystallinity and therefore the efficiency of a solar cell according to the present invention. As an additional advantage the number of scribbing steps, which are required to create individual cells out of a large area substrate on which various layers have been deposited, can be reduced. If several embedded wires are used which extend each with at least one end beyond the substrate, connection of the front electrode to a frame of the solar cell or cells is facilitated.

The present invention therefore provides a way to produce efficient thin film solar cells in a cost-efficient manner.

### BRIEF DESCRIPTION OF THE DRAWINGS

Further aspects and advantages of the present invention are explained in the following with respect to the enclosed figures illustrating preferred embodiments of the invention. Corresponding parts of different embodiments are marked with identical reference numerals.

FIG. 1 shows a cross-section of an exemplary embodiment of a solar cell according to the present invention.

FIG. 2 shows how a wire is embedded in the substrate of a solar cell according to FIG. 1.

FIG. 3 shows an exemplary embodiment of a prefabricated base part for a solar cell according to FIG. 1.

FIG. 4 shows schematically an exemplary embodiment of an apparatus for manufacturing solar cells according to FIG. 1.

### DETAILED DESCRIPTION

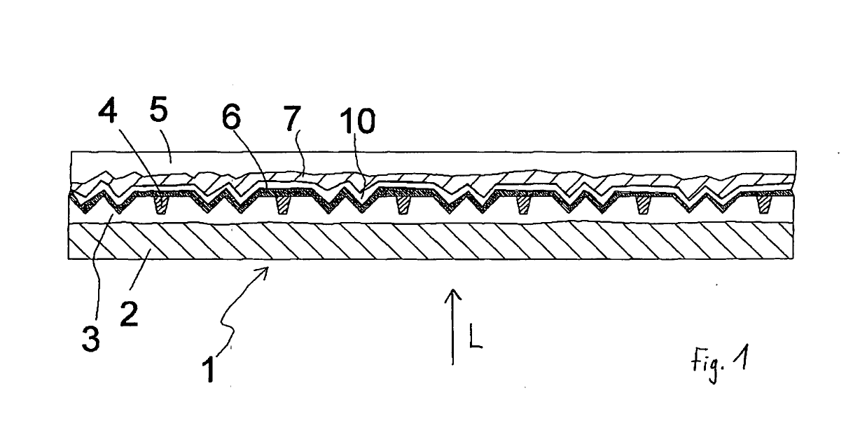

The embodiment of a solar cell 1 shown schematically in a cross-section view by FIG. 1 comprises a glass panel 2 which is coated by an anti-reflective layer 3 of silicon nitride. The panel 2 and the anti-reflective layer 3 form a substrate for the solar cell 1. At least one metal wire 4 is embedded in the anti-reflective layer 3. The at least one wire 4 forms the front electrode of the solar cell 1. The solar cell 1 also comprises a back electrode 5 which is formed by a metal film and semiconductor layers 6 and 7 which are arranged between the front electrode 4 and the back electrode 5. As indicated in FIG. 1 the interface between the panel 2 and the anti-reflective layer 3 is smooth whereas the interface between the anti-reflective layer 3 and the semiconductor layer 6 is textured comprising sloped sections.

The terms “front” and “back” refer to the direction in which the solar cell 1 is oriented during use to convert light into electric power. The direction of incident light during use is indicated in FIG. 1 by the arrow L.

In the present example the back electrode 5 is made of aluminium and the semiconductor layers 6 and 7 of p-doped silicon and n-doped silicon, respectively. It is both possible to arrange the p-doped semiconductor adjacent to the back electrode 5 and the n-doped semiconductor adjacent to the front electrode 4 or the n-doped semiconductor layer adjacent to the back electrode 5 and the p-doped semiconductor layer adjacent to the front electrode 4. Of course, several n-doped and p-doped semiconductor layers may be used instead of just one p-doped and one n-doped layer as shown. Instead of silicon other semiconductor materials, especially germanium or silicon-germanium compounds may also be used.

To form the front electrode 4 at least one metal wire is mechanically embedded in the substrate 2, 3 in such a way that a first part of its cross-section is surrounded by the substrate 2, 3 and a second part of its cross-section is exposed to and contacted by semiconductor material 6. The semiconductor material 6 covering the front electrode 4 can be part of the semiconductor layer 6. However, it is sometimes advantageous to cover the front electrode 4 by a separate layer of semiconductor material which is doped to reduce surface recombinations or more precisely interface recombinations, and improve the electrical connection of the front electrode 4 to the semiconductor layer 6. The doping of such semiconductor material is usually of the same kind (i.e. p-doped) as the adjacent semiconductor layer 6 but has a different concentration of dopants, especially a higher concentration.

As the least one metal wire 4 forming the front electrode is not transparent, a fraction of incident light is lost to shadowing effects. As this fraction cannot be transformed into electric power, the front electrode 4 should cover less than 20% of the substrate 2, 3, preferably less than 10%. However, if charge carriers created in the semiconductor layers 6 and 7 have to travel too far to reach the front electrode 4, power is lost due recombination processes in the semiconductor layer 6. Generally, the efficiency of the solar cell is best if the front electrode covers 2% to 8% of the substrate, preferably 3% to 7%. The at least one wire 4 which forms the front electrode has a cross-section of less than 200 μm, especially less than 130 μm. The smaller the wire, the smaller are shadowing effects. However, smaller wires are increasingly difficult to handle. Best results have been achieved with wires having a cross-section of 30 μm to 100 μm, especially 40 μm to 70 μm.

In the embodiment shown in FIG. 1 several metal wires 4 are arranged in parallel lines, although other geometrical arrangements are also possible. To keep ohmic losses within the semiconductor layer 6 small, the distance between neighbouring wires 4 is less than 3 mm, especially 0.2 mm to 2.5 mm wide. The embodiment shown, the distance between neighbouring wires is between 0.3 mm and 0.8 mm. The wires can also be arranged as a net, preferably a net with quadratic meshes.

As indicated in FIG. 1 the wire 4 has a non-circular cross-section. It has been found that wires with a triangular or quadrangular cross-section, especially with a cross-section in the shape of a parallelepiped as shown, can be embedded in a substrate more easily.

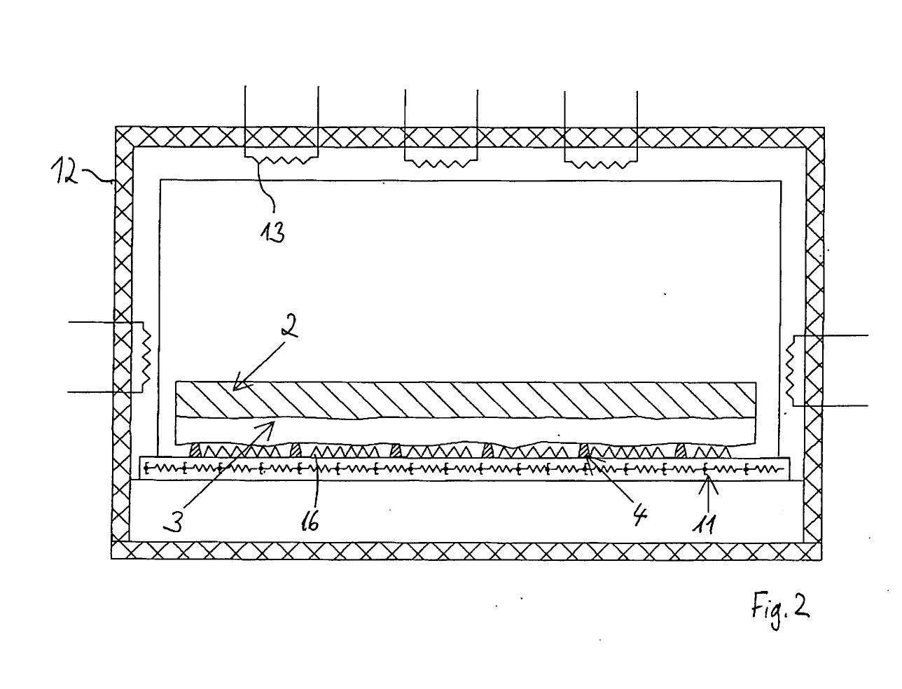

FIG. 2 shows how the at least one metal wire 4 is embedded in the substrate which comprises the glass panel 2 and the anti-reflective layer 3. The wire 4 is placed in parallel lines on a surface 16 which is in the example shown provided on a heating plate 11. The substrate 2, 3 is placed on top of the wire 4. The metal wire 4 and/or the substrate 2, 3 are then heated so that the surface of the substrate 2, 3 contacting the metal wire 4 becomes soft and the substrate 2, 3 sinks towards the surface 11 thus embedding the wire 4. The embedding process can be facilitated if the wire 4 is pressed into the substrate 2, 3. Of course, it is also possible to place the wire 4 on top of the substrate 2, 3 and press it into it.

In the example shown the substrate 2, 3 is placed in a chamber 12 and heated electrically by the heating plate 11 and heating facilities 13 of the chamber 12.

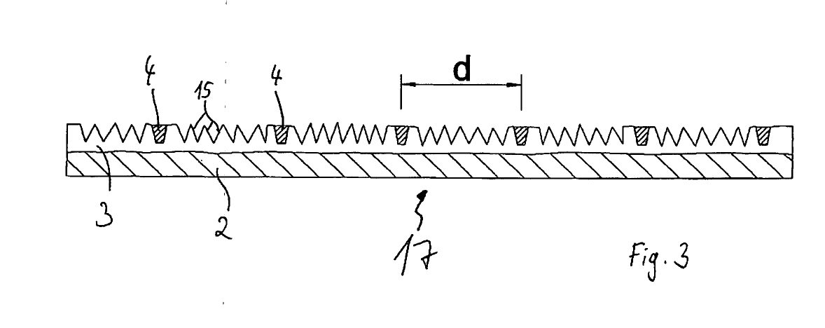

The substrate, which comprises the glass panel 2 and the anti-reflective layer 3, and the embedded wires 4 form a prefabricated base part 17, which is shown in FIG. 3, for manufacturing solar cells according to FIG. 1. At lest one end of the at least one wire 4 extends beyond the substrate 2, 3 for connection to a frame of a solar module (not shown). Solar modules comprise several solar cells which are electrically connect to provide electrical power.

The substrate surface, in which the at least one metal wire 4 is embedded and onto which semiconductor layers are to be deposited, can be textured to improve efficiency of a solar cell, for example said texture can comprise sloped surface sections 15. Sloped surface sections 15 which are inclined by an angle of 40° to 60° with respect to a geometrical plane parallel to the substrate divert incident light so that it travels along a skewed path through the semiconductor layers 6, 7. This increases the fraction of light that is absorbed and converted to electric power. Sloped surface sections 15 can be created by a suitable texture of the surface 16 in FIG. 2 against which the substrate is pressed for embedding the wire 4. For example, the surface 16 can comprise small pyramids.

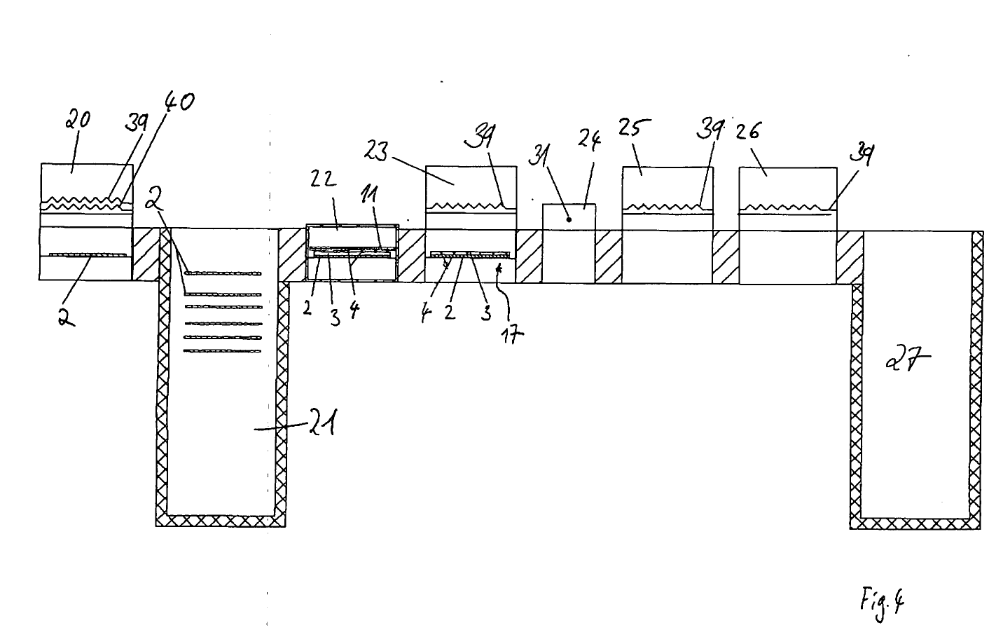

With reference to FIG. 4 an example for a method for manufacturing a solar cell according to the invention and a base part for such a solar cell are described. FIG. 4 shows schematically an apparatus suitable for manufacturing solar cells according to the invention. The apparatus consists basically of a series of chambers 20 to 27 which are connected by slot-shaped openings through which glass panels 2 are moved by means of a conveyor (not shown).

For the deposition of various layers on glass panels hot wire chemical vapor deposition which is also called catalytic chemical vapor deposition (cat-CVD) is preferred. For the hot wire chemical vapor deposition process (HWCVD) the glass panel is exposed to silane (SiH₄) and hydrogen (H₂) with a total pressure of about 10⁻¹ to 10⁻² mbar, preferably of about 2-10⁻² mbar.

For deposition of the anti-reflective nitride layer 3 ammonia (NH₃) is added in chamber 20 to the silane, for example 3 parts ammonia for 1 part silane. The silane and ammonia molecules are broken up into their constituents by use of catalytic surfaces 39, 40, preferably metallic surfaces. The decomposition of silane molecules can be achieved efficiently by catalytic surfaces 39 containing, for example, tantalum molybdenum and/or tungsten. It has been found that for the decomposition of ammonia molecules catalytic surfaces 40 containing nickel work especially well.

In the example illustrated in FIG. 4 the catalytic surface 39 for decomposition of silane molecules is provided as a tungsten wire 40 which is heated to a temperature above 800° C., especially about 850° C. to 1800° C. The hot catalytic surface converts silane molecules into radicals and ions, that are similar to di- and tri-silane molecules, which leads to high deposition rates which are mostly independent of temperature fluctuations of if the temperature of the substrate is at or above 600° C. Furthermore, such silicon-hydrogen ions, molecules and radicals deposit only to a small extent on colder walls of the deposition chamber. Hence, the temperature of the catalytic surface should be chosen in such a way that the amount of such silicon-hydrogen ions, molecules and radicals is as large as possible and the amount of Si-vapor small. Favorable results are achieved with tantalum wires at 900° C. to 1400° C. HWCVD may also be used to deposit Ge or SiGe layers if GeH₄ is used instead of SiH₄ or added to it, respectively.

The catalytic surface 40 for the decomposition of ammonia molecules is provided as a nickel wire 39. The nickel wire 39 is heated to a temperature above 500° C., especially 550° C. to 1000° C. The wires 39, 40 are heated by an electrical current of up to 20 A.

The constituents of silane and ammonia form a hydrogenated silicon nitride layer 3 on the glass panel 2. Typically the silicon nitride layer 3, which is deposited in chamber 20, contains about 1% to 10% hydrogen.

It has been found that elevated temperatures of the glass panel 2 facilitate crystallization of deposited semiconductor layers. In the case of silicon layers temperatures of about 600° C. to 800° C. are advantageous. By hot wire chemical vapor deposition on heated glass panels 2 crystalline layers can be achieved in a comparatively short time. Of course, good crystallization with large grains can also be achieved by heat treatment at such temperatures after the deposition process, so that elevated temperatures of the glass panels 2 during deposition are not necessary.

Chamber 21 is a heating station in which a number of substrates comprising glass panels 2 and the anti-reflective layer 3 can be heated for the manufacturing process. The heating station 21 comprises a loading bay which may contain, for example, 15 to 45 glass panels. The glass panels are heated to a temperature of 600° C. to 800° C. and kept in that temperature range during the manufacturing process described in the following.

When a batch of glass panels 2 is heated to the working temperature of about 600° C. to 800° C. the glass panels are moved one after another through the chambers 21 to 26.

In a next step the metal wires forming the front electrode 4 are arranged in parallel lines on the coated substrate 2, 3 as indicated in chamber 22. The wires 4 are then pressed into the heated substrate comprising the glass panel 2 and the anti-reflective layer 3. The wires 4 are pressed into the anti-reflective layer 3 by a heating plate 11 which heats the wires to a temperature of about 700° C. to 1000° C., especially 750° C. to 900° C. During this embedding process the glass panel 2 has a temperature of about 650° C. to 900° C. The substrate can be locally heated by the wire. However, the temperature difference between wire 4 and substrate 2, 3 should not exceed 100 K to avoid thermal stresses which might damage the substrate 2, 3.

The substrate 2, 3 with the embedded wire 4 is a prefabricated base part 17 for manufacturing a solar cell as shown in FIG. 3. In the example shown the base parts are more or less immediately used for manufacturing solar cells. However, such base parts 17 can also be stored and used later in a different apparatus.

In a further step indicated in chamber 23 a p-doped silicon layer is deposited onto the base part 17. This is also done by hot wire chemical vapor deposition. The substrate is exposed to an atmosphere containing equal parts of SiH₄ and H₂ and about 1% B₂H₆ at a pressure of 0.02 mbar to 0.5 mbar. Preferably, silane is blown into the chamber in a direction perpendicular to the substrate, especially from above, or opposite to the movement of the conveyor. A heated tungsten, molybdenum or tantalum wire 39 is used as a catalytic surface to decompose silane molecules. The p-doped silicon layer 6 deposited in this way preferably has a thickness of 50 nm to 1000 nm.

During the deposition of the p-doped silicon layer 6 the glass panel 2 is preferably kept at a temperature of about 600 to 700° C. which facilitates the deposition and crystallization. It is advantageous to keep the wall of the deposition chambers 23, 25, 26 cool (i.e. room temperature or at least 100 K below the temperature of the substrate) to keep deposition onto chamber walls at a minimum. Crystallization can be further enhanced by laser annealing or zone melting recrystallization in an adjacent chamber 24 by use of a laser 31 or halogen lamp.

In subsequent steps indicated in chambers 25 and 26 an intrinsic silicon layer and an n-doped silicon layer are deposited. These layers are also deposited by hot wire chemical vapor deposition for which catalytic wires 39 are used as in chamber 23. For depositing the n-doped silicon layer PH₃ can be used as dopant gas instead of B₂H₆. Of course additional deposition chambers may be added for the deposition of additional semiconductor layers.

After all silicon layers have been deposited the back electrode is deposited as a metallic layer 5, preferably as an aluminium film. To avoid contamination of deposition chambers 23, 25, 26 this is done in a separate apparatus (not shown).

After deposition of the last semiconductor layer substrate is moved into chamber 27. Like chamber 21, in which a batch of glass panels 2 was heated, chamber 27 is designed to hold a batch substrates which are slowly cooled down to room temperature in chamber 27.

The method described above for manufacturing solar cells can also be used to grow semiconductor layers on substrates for other purposes. Thus the invention also comprises a method for the growth of a semiconductor layer on a substrate, said method comprising the steps of heating the substrate to a temperature of at least 500° C. and depositing the semiconductor layer onto the heated substrate by hot wire chemical vapor deposition.

### LIST OF REFERENCE NUMERALS

1 solar cell
2 substrate
3 anti-reflective layer
4 front electrode
5 back electrode
6 p-doped semiconductor layer
7 n-doped semiconductor layer
8 doped semiconductor material
10 instrinsic semiconductor layer
11 heating plate
12 chamber wall
13 heating facility
15 sloped surface sections
16 surface
17 base part
20 deposition chamber
21 heating chamber
22 embedding chamber
23 deposition chamber
24 laser-annealing chamber
25 deposition chamber
26 deposition chamber
27 cooling chamber
39 catalytic wire (W, Mo or Ta)
40 catalytic wire (Ni)

What is claimed is:

1. Solar cell comprising
at least one p-doped semiconductor layer and at least one n-doped semiconductor layer arranged on a substrate between a front electrode and a back electrode, the front electrode being arranged between the substrate and the semiconductor layers, wherein the front electrode is formed by at least one metal wire,
wherein the at least one p-doped semiconductor layer and the at least one n-doped semiconductor layer are crystalline.

2. Solar cell according to claim 1, wherein the at least one metal wire is placed on the substrate.

3. Solar cell according to claim 2, wherein the at least one metal wire is embedded in the substrate in such a way that a first part of its cross-section is surrounded by the substrate and a second part of its cross-section is contacted by semiconductor material so that the at least one metal wire is electrically connected to the n- and p-doped semiconductor layers.

4. Solar cell according to claim 1, wherein at least one end of the at least one wire extends beyond the substrate.

5. Solar cell according to claim 1, wherein the substrate comprises an anti-reflective layer.

6. Solar cell according to claim 5, wherein the anti-reflective layer is made of silicon nitride.

7. Solar cell according to claim 1, wherein the at least one metal wire has a non-circular cross section.

8. Solar cell according to claim 1, wherein the at least one metal wire has a triangular or quadrangular cross section.

9. Solar cell according to claim 1, wherein an interface between the substrate in which the at least one metal wire is embedded and the adjacent semiconductor layer is textured.

10. Solar cell according to claim 9, wherein the texture of the interface comprises sloped surface sections.

11. Solar cell according to claim 10, wherein the sloped surface sections are inclined by an angle of 40° to 60° with respect to a geometrical plane parallel to the substrate.

12. Method for manufacturing a solar cell according to claim 1, said method comprising the following steps:
placing at least one metal wire on a substrate,
depositing at least one n-doped and at least one p-doped semiconductor layer onto the substrate in such a way that these semiconductor layers are electrically connected to the at least one wire, and
placing a back electrode on top of the semiconductor layers,
wherein the substrate is heated to achieve that the semiconductor layers are crystalline.

13. Method according to claim 12, wherein the at least one metal wire is embedded in the substrate in such a way that only part of its cross-section is surrounded by the substrate.

14. Method according to claim 12, wherein the semiconductor layers are deposited by a vapor deposition method.

15. Method according to claim 14, wherein the semiconductor layers are deposited by a chemical vapor deposition method.

16. Method according to claim 15, wherein the semiconductor layers are deposited by hot wire chemical vapor deposition.

17. Method according to claim 12, wherein the substrate is heated during deposition of the semiconductor layers.

18. Method according to claim 17, wherein the substrate is heated to a temperature of at least 500° C. during deposition of the semiconductor layers.

19. Method according to claim 12, wherein the substrate is heated after the deposition of the semiconductor layers.

20. Method according to claim 12, wherein a silicon nitride layer is grown by hot wire chemical vapor deposition using ammonia and a catalytic surface containing nickel.
